(19) United States
(12) Patent Application Publication
(10) Pub. No.: US 2005/0257824 A1
(43) Pub. Date: Nov. 24, 2005

(54) Photovoltaic cell including capping layer

(76) Inventors: Michael G. Maltby, Wayne, OH (US); Dean M. Giolando, Toledo, OH (US); Yann Roussillon, Toledo, OH (US)

Correspondence Address: STEPTOE & JOHNSON LLP;Attn: Docket Administrator - Box USPTO, 1330 Connecticut Avenue, NW, Washington, DC, 20036, US

(21) Appl. No.: 10/851,652

(22) Filed: May 24, 2004

(51) Int. Cl. H01L 31/00

(52) U.S. Cl. 136/252

(57) ABSTRACT

A photovoltaic cell can include a thin capping layer between a buffer layer and a first semiconductor layer to chemically and electrically isolate the buffer layer from the first semiconductor layer.

### TECHNICAL FIELD

This invention relates to photovoltaic cells.

### BACKGROUND

During the fabrication of photovoltaic devices, layers of semiconductor material can be applied to a substrate with one layer serving as a window layer and a second layer serving as the absorber layer. The window layer allows the penetration of solar energy to the absorber layer, where the energy is converted into electrical energy. In order to enhance performance of the photovoltaic device, it can be desirable to reduce the thickness of the window layer to allow a greater percentage of the incident solar energy to penetrate to the absorber layer resulting in a more efficient photovoltaic device.

### SUMMARY

In general, a photovoltaic cell substrate includes a transparent conductive layer on a surface of the substrate, and a capping layer over the transparent conductive layer electrically isolating the transparent conductive layer.

The substrate can include a first semiconductor layer over the capping layer. The first semiconductor layer can include a binary semiconductor, such as a Group II-VI semiconductor, for example, the first semiconductor can include CdS. The photovoltaic substrate can also include a second semiconductor layer over the first semiconductor layer. The second semiconductor layer can be a binary semiconductor, such as a Group II-VI semiconductor, for example, the second semiconductor can include CdTe.

In certain circumstances, the capping layer can chemically isolate the transparent conductive layer from the first semiconductor layer. The capping layer can include silicon dioxide, titanium dioxide, dialuminum trioxide, or diboron trioxide.

In another aspect, a photovoltaic cell can include a semiconductor layer, a substrate having a surface supporting the semiconductor layer, a transparent conductive layer on the surface of the substrate between the semiconductor layer and the substrate, and a capping layer between the transparent conductive layer and the semiconductor layer. The capping layer can electrically and chemically isolate the transparent conductive layer from the semiconductor layer.

In yet another aspect, a system for generating electrical energy can include a multilayered photovoltaic cell including a capping layer over a transparent conductive layer and electrical connections connected to the photovoltaic cell for collecting electrical energy produced by the photovoltaic cell. The photovoltaic cell can include a first semiconductor layer on top of the capping layer. The system can include a photovoltaic cell that includes a second semiconductor layer on top of the first semiconductor layer.

In another aspect, a method of making a photovoltaic cell substrate includes placing a transparent conductive layer on a substrate, placing a capping layer over the transparent conductive layer, electrically isolating the transparent conductive layer. The method can include placing a transparent conductive layer on a substrate by depositing a uniform layer of a transparent conductive oxide on the substrate. The transparent conductive oxide can be a tin oxide.

A method of manufacturing a photovoltaic cell can include placing a first semiconductor layer on a substrate, the substrate having a surface, placing a transparent conductive layer on the surface of the substrate, and placing a capping layer between the transparent conductive layer and the first semiconductor layer. The method can also include a second semiconductor layer over the first semiconductor layer. Placing a transparent conductive layer on the surface of a substrate can include depositing a thin transparent conductive layer on the substrate. Placing a capping layer between the transparent conductive layer and the first semiconductor layer can include depositing a thin layer on the transparent conductive layer.

The details of one or more embodiments are set forth in the accompanying drawings and the description below. Other features, objects, and advantages will be apparent from the description and drawings, and from the claims.

### DESCRIPTION OF DRAWINGS

FIG. 1 is a schematic of a partially coated substrate indicating deposited layers cells with different capping layer thicknesses.

### DETAILED DESCRIPTION

A photovoltaic cell can be constructed of a series of layers of semiconductor materials deposited on a glass substrate. In an example of a common photovoltaic cell, the multiple layers can include: a bottom layer that is a transparent conductive layer, a capping layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. Additional layers can be added using other techniques such as sputtering. Electrical conductors can be connected to the top and the bottom layers respectively to collect the electrical energy produced when solar energy is incident onto the absorber layer. A top substrate layer can be placed on top of the top layer to form a sandwich and complete the photovoltaic cell.

The bottom layer can be a transparent conductive layer, and can be for example a transparent conductive oxide such as tin oxide or tin oxide doped with fluorine. Deposition of a semiconductor layer at high temperature directly on the transparent conductive oxide layer can result in reactions that negatively impact of the performance and stability of the photovoltaic device. Deposition of a capping layer of material with a high chemical stability (such as silicon dioxide, dialuminum trioxide, titanium dioxide, diboron trioxide and other similar entities) can significantly reduce the impact of these reactions on device performance and stability. The thickness of the capping layer should be minimized because of the high resistivity of the material used. Otherwise a resistive block counter to the desired current flow may occur.

The thickness of the capping layer can be from greater than about 10 Å. In certain circumstances, the thickness of the capping layer can be less than about 500 Å. For example, the thickness of the capping layer can be greater than 20 Å, greater than 50 Å, greater than 75 Å or greater than 100 Å. For example, the thickness of the capping layer can be less than 250 Å, less than 200 Å, less than 150 Å, less than 125 Å, less than 100 Å, less than 75 Å or less than 50 Å. Complete coverage of the transparent conductive oxide layer may not occur. The capping layer can reduce the surface roughness of the transparent conductive oxide layer by filling in irregularities in the surface, which can aid in deposition of the window layer and can allow the window layer to have a thinner cross-section. The reduced surface roughness can help improve the uniformity of the window layer. Other advantages of including the capping layer in photovoltaic cells can include improving optical clarity, improving consistency in band gap, providing better field strength at the junction and providing better device efficiency as measured by open circuit voltage loss.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof. An example of a window layer and absorbing layer is a layer of CdS coated by a layer of CdTe. A top layer can cover the semiconductor layers. The top layer can include a metal such as, for example, nickel or aluminum.

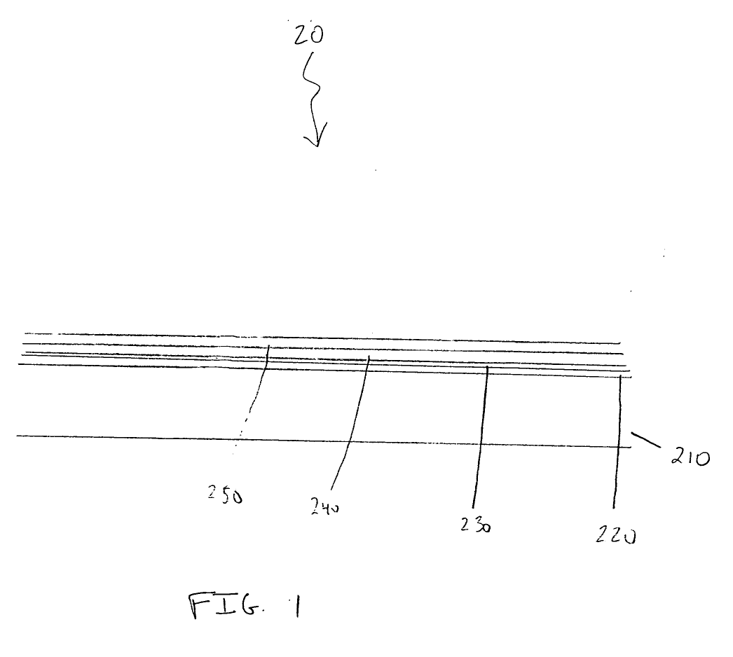

Referring to FIG. 1, a cross section of the first four layers of a photovoltaic cell 20 has substrate 210 upon which is deposited the first four layers used in the photovoltaic cell. The first layer deposited on the substrate is a thin film of a transparent conductive layer 220. This layer 220 can be a transparent conductive oxide, such as a metallic oxide like tin oxide, which can be doped with, for example, fluorine. Layer 220 can be deposited between the front contact and the first semiconductor layer 240, and can have a resistivity sufficiently high to reduce the effects of pinholes in the first semiconductor layer 240. Pinholes in the first semiconductor layer 240 can result in shunt formation between the second semiconductor layer 250 and the first contact resulting in a drain on the local field surrounding the pinhole. A small increase in the resistance of this pathway can dramatically reduce the area affected by the shunt. A capping layer 230 can be provided to supply this increase in resistance. The capping layer 230 can be a very thin layer of a material with high chemical stability. The capping layer 230 can have higher transparency than a comparable thickness of semiconductor material having the same thickness. Examples of materials that are suitable for use as a capping layer include silicon dioxide, dialuminum trioxide, titanium dioxide, diboron trioxide and other similar entities. Capping layer 230 can also serve to isolate the transparent conductive layer 220 electrically and chemically from the first semiconductor layer 240 preventing reactions that occur at high temperature that can negatively impact performance and stability. The capping layer 230 can also provide a conducive surface that can be more suitable for accepting deposition of the first semiconductor layer 240. For example, the capping layer 230 can provide a surface with decreased surface roughness. When using a buffer layer 220 and a capping layer 230, the first semiconductor layer 240 can be thinner than in the absence of the buffer layer. For example, the first semiconductor layer 240 can have a thickness of greater than about 10 nm and less than about 500 nm. For example, the first semiconductor layer can have a thickness greater than 20 nm, greater than 50 nm, greater than 100 nm, or greater than 200 nm and less than 400 nm, less than 300 nm, less than 250 nm, or less than 150 nm

The first semiconductor layer 240 can serve as a window layer for the second semiconductor layer 250. By being thinner, the first semiconductor layer 240 allows greater penetration of the shorter wavelengths of the incident light to the second semiconductor layer 250. The first semiconductor layer 240 can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof. It can be a binary semiconductor, for example it can be CdS. The second semiconductor layer 250 can be deposited onto the first semiconductor layer 240. The second semiconductor 250 can serve as an absorber layer for the incident light when the first semiconductor layer 240 is serving as a window layer. Similar to the first semiconductor layer 240, the second semiconductor layer 250 can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic cells can include a conveyor, for example a roll conveyor with rollers. Other types of conveyors are possible. The conveyor transports substrate into a series of one or more deposition stations for depositing layers of material on the exposed surface of the substrate. The deposition chamber can be heated to reach a processing temperature of not less than about 450° C. and not more than about 700° C., for example the temperature can range from 450-550, 550-650°, 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations each station with its own vapor distributor and supply. The distributor can be in the form of a spray nozzle with varying nozzle geometries to facilitate uniform distribution of the vapor supply.

The bottom layer can be a transparent conductive layer. On top of and at least covering the transparent conductive layer in part, is a thin capping layer. The next layer deposited is the first semiconductor layer, which can serve as a window layer and can be thinner based on the use of a transparent conductive layer and the capping layer. The next layer deposited is the second semiconductor layer, which serves as the absorber layer. Other layers can be deposited or otherwise placed on the substrate throughout the manufacturing process as needed In particular examples, devices including capping layers were fabricated as follows. The substrate was soda lime float glass. A first thin film of SnO₂:F was commercially deposited by atmospheric pressure chemical vapor deposition (APCVD). Conductivity and transparency of this film suit it to serving as the front contact layer for the photovoltaic device.

A second layer of APCVD deposited, un-doped SnO₂ was used in some of the test devices. This layer is transparent, but conductivity of this layer is significantly lower than the fluorine doped SnO₂ layer. This layer can be called a buffer layer, since it can be used to prevent shunting between the transparent contact and other critical layers of the device. One version of this layer was commercially deposited on the float line and the other version was deposited onto the commercial SnO₂:F layer during device fabrication for these experiments. In both cases, the films were deposited at temperatures in excess of 550 degrees Celsius.

A silicon dioxide capping layer was deposited using electron-beam evaporation. This layer was deposited directly on the SnO₂ or SnO₂:F layers. The silicon dioxide had a thickness tested ranging among the various devices fabricated of 10 Angstroms to 500 Angstroms. Other materials and deposition methods were used to fabricate capping layers in the devices. Semiconductors used were CdS for the window layer and CdTe for the absorber/collector layer. Deposition of these materials was accomplished using close space sublimation techniques at temperatures in the range of 550 to 650° C.

Devices were finished with appropriate back contact methods know to create good devices from CdTe PV materials. Testing for results of these devices was performed at initial efficiency, and after accelerated stress testing using I/V measurements on a solar simulator. Testing for impact of chemical breakdown in the front contact and blocking layers was done with spectrophotometer reflectance measurements, conductivity (sheet resistance) measurements, and in extreme cases thermal breakdown of these films was demonstrated by etch removal of these films with an acid (HNO₃) that would not impact them unless they had been chemically changed.

The presence of a thin capping layer of silicon dioxide (e.g., having a thickness of 100 Angstroms, 75 Angstroms or 50 Angstroms) and a CdS layer of about 1000 Angstroms increased the open circuit voltage of the devices by at least 3-12% and resistive load efficiencies to over 13% initially and over 11% after accelerated stress testing. The capping layer can allow significantly thinner window layers to be fabricated (e.g., having a thickness of 750 Angstroms, 500 Angstroms, or 250 Angstroms) to produce devices with efficiencies greater than 10%.

A number of embodiments have been described. Nevertheless, it will be understood that various modifications may be made without departing from the spirit and scope of the invention. For example, the semiconductor layers can include a variety of other materials, as can the materials used for the buffer layer and the capping layer. Accordingly, other embodiments are within the scope of the following claims.

1. A photovoltaic cell substrate comprising:
a transparent conductive layer on a surface of the substrate; and
a capping layer over the transparent conductive layer electrically isolating the transparent conductive layer.

2. The substrate of claim 1 further comprising a first semiconductor layer over the capping layer.

3. The substrate of claim 2 wherein the capping layer chemically isolates the transparent conductive layer from the semiconductor layer.

4. The substrate of claim 2 wherein the first semiconductor layer comprises a binary semiconductor.

5. The substrate of claim 2 wherein the first semiconductor layer comprises CdS.

6. The substrate of claim 2 further comprising a second semiconductor layer over the first semiconductor layer.

7. The substrate of claim 6 wherein the second semiconductor layer comprises a binary semiconductor.

8. The substrate of claim 6 wherein the second semiconductor layer comprises CdTe.

9. The substrate of claim 1 wherein the capping layer comprises silicon dioxide.

10. The substrate of claim 1 wherein the capping layer comprises titanium dioxide.

11. The substrate of claim 1 wherein the capping layer comprises dialuminum trioxide.

12. The substrate of claim 1 wherein the capping layer comprises diboron trioxide.

13. The substrate of claim 2 wherein the capping layer isolates the transparent conductive oxide layer from contact with the first semiconductor layer.

14. A photovoltaic cell comprising:
a semiconductor layer;
a substrate having a surface, the substrate supporting the semiconductor layer;
a transparent conductive layer on the surface of the substrate between the semiconductor layer and the substrate; and
a capping layer between the transparent conductive layer and the semiconductor layer.

15. The photovoltaic cell of claim 14 wherein the capping layer chemically isolates the transparent conductive layer from the semiconductor layer.

16. The photovoltaic cell of claim 14 wherein the capping layer electrically isolates the transparent conductive layer from the semiconductor layer.

17. The photovoltaic cell of claim 14 wherein the capping layer electrically and chemically isolates the transparent conductive layer from the semiconductor layer.

18. The photovoltaic cell of claim 14 wherein the capping layer comprises silicon dioxide.

19. The photovoltaic cell of claim 14 wherein the capping layer comprises titanium dioxide.

20. The photovoltaic cell of claim 14 wherein the capping layer comprises dialuminum trioxide.

21. The photovoltaic cell of claim 14 wherein the capping layer comprises diboron trioxide.

22. The photovoltaic cell of claim 14 wherein the capping layer decreases the surface roughness of the transparent conductive layer.

23. A system for generating electrical energy comprising a multilayered photovoltaic cell, the photovoltaic cell including a capping layer over a transparent conductive layer; and
electrical connections connected to the photovoltaic cell for collecting electrical energy produced by the photovoltaic cell.

24. The system of claim 23 wherein the photovoltaic cell includes a first semiconductor layer on top of the capping layer.

25. The system of claim 24 wherein the first semiconductor layer comprises a binary semiconductor.

26. The system of claim 25 wherein the first semiconductor comprises CdS.

27. The system of claim 24 wherein the photovoltaic cell includes a second semiconductor layer on top of the first semiconductor layer.

28. The system of claim 27 wherein the second semiconductor layer comprises a binary semiconductor.

29. The system of claim 28 wherein the second semiconductor layer comprises CdTe.

30. A method of making a photovoltaic cell substrate comprising:
placing a transparent conductive layer on a substrate;
placing a capping layer over the transparent conductive layer, electrically isolating the transparent conductive layer.

31. The method of claim 31 wherein placing a transparent conductive layer on a substrate includes depositing a uniform layer of a transparent conductive oxide on the substrate.

32. The method of claim 31 wherein the transparent conductive oxide is tin oxide.

33. A method of manufacturing a photovoltaic cell comprising:
placing a first semiconductor layer on a substrate, the substrate having a surface;
placing a transparent conductive layer on the surface of the substrate;
placing a capping layer between the transparent conductive layer and the first semiconductor layer.

34. The method of claim 33 further comprising placing a second semiconductor layer over the first semiconductor layer.

35. The method of claim 33 wherein placing a transparent conductive layer on the surface of a substrate includes depositing a thin transparent conductive layer on the substrate.

36. The method of claim 35 wherein the transparent conductive layer comprises a transparent conductive oxide.

37. The method of claim 36 wherein the transparent conductive oxide comprises tin oxide.

38. The method of claim 33 wherein placing a capping layer between the transparent conductive layer and the first semiconductor layer includes depositing a thin layer on the transparent conductive layer.

39. The method of claim 33 wherein the capping layer comprises a thin layer of silicon dioxide.

40. The method of claim 33 wherein the capping layer comprises a thin layer of titanium dioxide.

41. The method of claim 33 wherein the capping layer comprises a thin layer of dialuminum trioxide.

42. The method of claim 33 wherein the capping layer comprises a thin layer of diboron trioxide.
